(19) United States
(12) Patent Application Publication
(10) Pub. No.: US 2013/0170146 A1
(43) Pub. Date: Jul. 4, 2013

(54) MEMORY ASSEMBLY

(71) Applicant: TEN-CHEN HO, Tu-Cheng (TW)

(72) Inventor: TEN-CHEN HO, Tu-Cheng (TW)

(73) Assignee: HON HAI PRECISION INDUSTRY CO., LTD., Tu-Cheng (TW)

(21) Appl. No.: 13/370,813

(22) Filed: Feb. 10, 2012

(30) Foreign Application Priority Data
Dec. 28, 2011 (CN) 201110447345.8

(51) Int. Cl. H05K 7/20

(52) U.S. Cl. 361/721

(57) ABSTRACT

A motherboard includes a circuit board, a memory slot, a memory, a heat-dissipating member, an electrically conductive latching element, and a grounding element. The grounding element includes two electrically conductive first securing members mounted on the circuit board. The first securing members are electrically connected to a ground layer of the circuit board. The latching element includes a latching portion abutting the heat-dissipating member and two hooking portions formed on two ends of the latching portion. The hooking portions respectively latch the first securing members.

### BACKGROUND

1. Technical Field

The present disclosure relates to a memory assembly.

2. Description of Related Art

In many server computers or personal computers, heat sinks are assembled to memories to dissipate heat from the memories. However, electromagnetic waves from the memories may couple with the heat sinks creating an antenna effect, producing electromagnetic interference.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present disclosure. Moreover, in the drawings, all the views are schematic, and like reference numerals designate corresponding parts throughout the several views.

FIG. 1 is an exploded, isometric view of a first exemplary embodiment of a motherboard.

FIG. 2 is an assembled, isometric view of the motherboard of FIG. 1.

FIG. 3 is an assembled, isometric view of a second exemplary embodiment of a motherboard.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

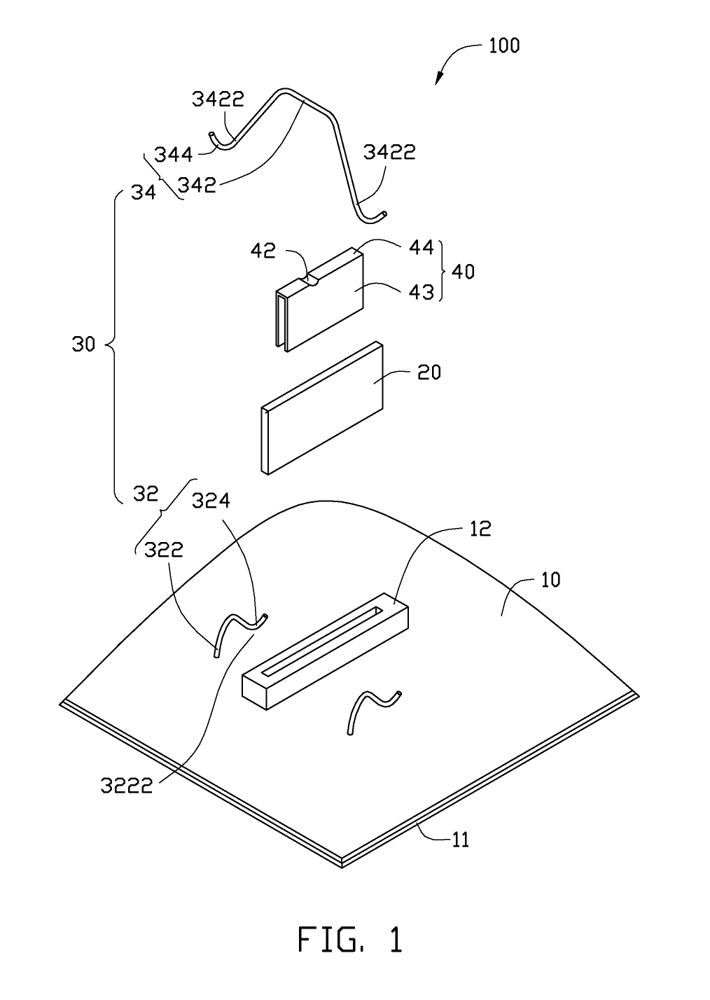

Referring to FIG. 1, a first embodiment of a motherboard 100 includes a circuit board 10, a memory slot 12, a memory 20, a grounding element 30, and a heat-dissipating member 40.

The memory slot 12 is mounted on the circuit board 10 to allow communication between the memory 20 and other elements on the circuit board 10.

The heat-dissipating member 40 is substantially U-shaped, and includes two opposite boards 43, and a connection portion 44 connected between top sides of the boards 43. A slot 42 is defined in the connection portion 44.

The grounding element 30 includes two conductive first securing members 32 and a conductive latching element 34. The first securing members 32 are substantially a reverse S-shaped structure, with one leg of the reverse S shorter than the other, and fixed on the circuit board 10 and respectively located at two opposite sides of the memory slot 12. A first terminal 322 of each first securing member 32 is fixed on the circuit board 10 and electrically connected to a ground layer 11 of the circuit board 10. A second terminal 324 of each first securing member 32 is above the circuit board 10 and there is a distance between the second terminal 324 and the circuit board 10 to form a gap 3222.

The latching element 34 includes a substantially n-shaped latching portion 342 and two hooking portions 344 extending out and up from two ends 3422 of the latching portion 342. The latching portion 342 is used to be engaged in the slot 42 of the heat-dissipating member 40. The hooking portions 344 are used to be latched with the corresponding first securing member 32.

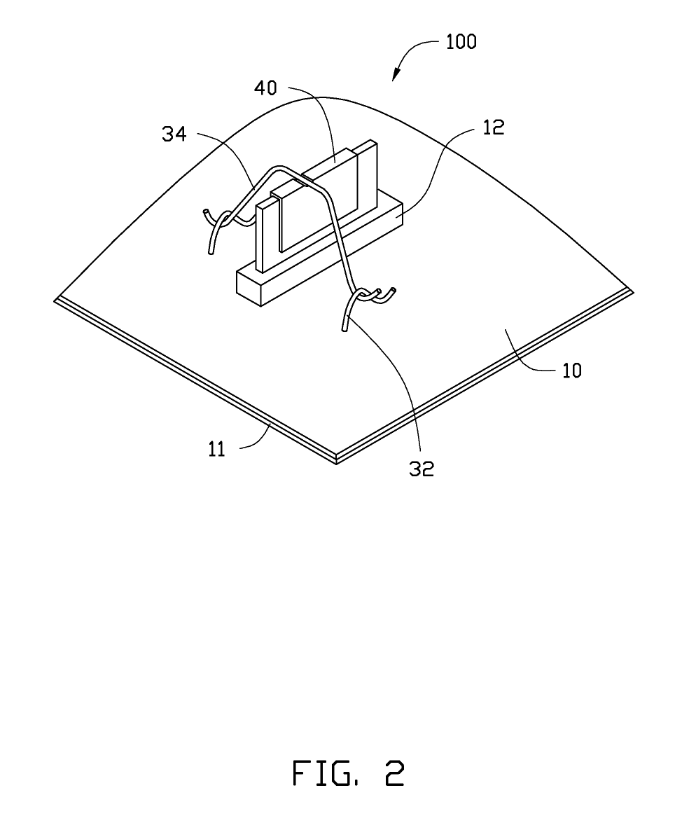

Referring to FIG. 2, in assembly, the memory 20 is inserted into the memory slot 12. The heat-dissipating member 40 is assembled on top of the memory 20. The boards 43 tightly abut opposite side surfaces of the memory 20. The connection portion 44 tightly abuts the top of the memory 20. The latching portion 342 is engaged in the slot 42 of the heat-dissipating member 40. The hooking portions 344 are located at the opposite sides of the heat-dissipating member 40 and hook the corresponding first securing member 32 through the corresponding gap 3222. Therefore, the latching portion 342 tightly abuts the heat-dissipating member 40 toward the circuit board 10.

When the memory 20 operates, electromagnetic (EM) waves from the memory 20 are directly grounded through the latching element 34, thereby avoiding having the EM waves coupling with and radiating from the heat-dissipating member 40.

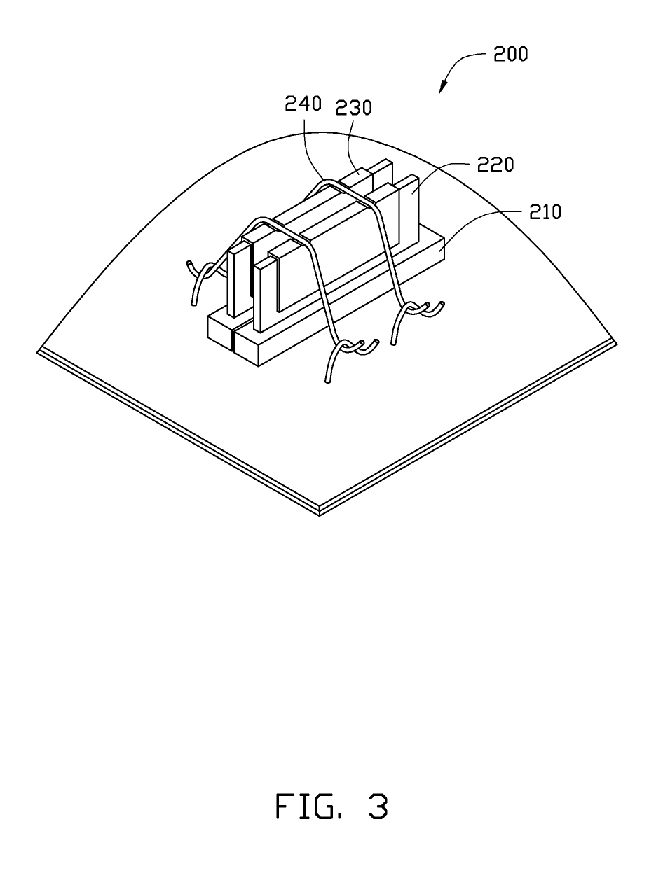

Referring to FIG. 3, a second embodiment of a motherboard 200 is similar to the first embodiment of the motherboard 100. In the second embodiment, the motherboard 200 includes two parallel memory slots 210, two memories 220, two heat-dissipating members 230, and two grounding elements 240. Two slots 232 are defined in a top of each heat-dissipating member 230 to receive the grounding elements 240. The working principle of the grounding element 240 in the second embodiment is the same as for the grounding element 30 in the first embodiment.

Although numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A motherboard comprising:
a circuit board comprising a ground layer;
a memory slot mounted on the circuit board;
a memory inserted into the memory slot;
a heat-dissipating member partially wrapping the memory; and
a grounding element comprising:
two conductive first securing members fixed to the circuit board and located at two opposite sides of the memory slot, wherein the first securing members are electrically connected to the ground layer of the circuit board; and
a conductive latching element comprising:
a latching portion abutting a top of the heat-dissipating member; and
two hooking portions formed on two ends of the latching portion to latch with the corresponding first securing member.

2. The motherboard of claim 1, wherein a first terminal of each first securing member is fixed on the circuit board and electrically connected to the ground layer.

3. The motherboard of claim 1, wherein there is a distance between a second terminal of each first securing member to form a gap between the second end of the first securing member and the circuit board, through which a corresponding hooking portion hooks the first securing member.

4. The motherboard of claim 1, wherein the hooking portions extend out and up from the corresponding ends of the latching portion.

5. The motherboard of claim 1, wherein a slot is defined in the top of the heat-dissipating member, the latching portion is engaged into the slot to press the heat-dissipating member.

6. A memory assembly to be mounted to a motherboard, the memory assembly comprising:
a memory inserted into a memory slot of the motherboard;
a heat-dissipating member partially wrapping the memory; and
a grounding element comprising:
two conductive first securing members fixed to the motherboard and located at two opposite sides of the memory slot, wherein the first securing members are electrically connected to a ground layer of the motherboard; and
a conductive latching element comprising:
a latching portion abutting a top of the heat-dissipating member; and
two hooking portions formed on two ends of the latching portion to latch with the corresponding first securing member.

7. The memory assembly of claim 6, wherein a first terminal of each first securing member is fixed on the motherboard and electrically connected to the ground layer.

8. The memory assembly of claim 6, wherein there is a distance between a second terminal of each first securing member to form a gap between the second end of the first securing member and the motherboard, through which a corresponding hooking portion hooks the first securing member.

9. The memory assembly of claim 6, wherein the hooking portions extend out and up from the corresponding ends of the latching portion.

10. The memory assembly of claim 6, wherein a slot is defined in the top of the heat-dissipating member, the latching portion is engaged into the slot to press the heat-dissipating member.
